(19) United States
(12) Patent Application Publication
(10) Pub. No.: US 2026/0025900 A1
(43) Pub. Date: Jan. 22, 2026

(54) OBSERVATION DEVICE FOR AN EUV LIGHT SYSTEM, AND CORRESPONDING EUV LIGHT SYSTEM

(71) Applicant: TRUMPF Lasersystems for Semiconductor Manufacturing SE, Ditzingen (DE)

(72) Inventors: Boris Regaard, Stuttgart (DE); Stefan Piehler, Stuttgart (DE); Oliver Schlosser, Filderstadt (DE); Tolga Ergin, Bietigheim-Bissingen (DE)

(21) Appl. No.: 19/346,585

(22) Filed: Oct. 1, 2025

Related U.S. Application Data
(63) Continuation of application No. PCT/EP2024/059296, filed on Apr. 5, 2024.

(30) Foreign Application Priority Data
Apr. 6, 2023 (DE) 10 2023 108 855.6

(51) Int. Cl. H05G 2/00; G03F 7/00

(52) U.S. Cl. CPC H05G 2/0086; G03F 7/70033

(57) ABSTRACT

An observation device for an extreme ultraviolet (EUV) light system for observing a material droplet for EUV light generation includes an optical unit for focusing a measurement laser beam onto the material droplet and for directing light reflected by the material droplet along a predefined beam path, a sensor system arranged at an end of the beam path for detecting the reflected light, and at least one light-blocking element arranged between the optical unit and the sensor system, as viewed along the beam path, for keeping away interfering reflections of the measurement laser beam, which emanate from the optical unit in a direction of the sensor system at least in a central region of the beam path, such that at least a part of the reflected light can reach the sensor system along the beam path in spite of the light-blocking element.

### CROSS REFERENCE TO RELATED APPLICATIONS

This application is a continuation of International Application No. PCT/EP2024/059296 (WO 2024/209029 A1), filed on Apr. 5, 2024, and claims benefit to German Patent Application No. DE 10 2023 108 855.6, filed on Apr. 6, 2023. The aforementioned applications are hereby incorporated by reference herein.

### FIELD

Embodiments of the present invention relate to an observation device for an EUV laser system for determining a position of a material droplet for EUV light generation. Embodiments of the invention further relate to an EUV laser system equipped therewith.

### BACKGROUND

EUV light, in particular light with a wavelength in the range of about 10 nm to about 121 nm, can be useful for various applications. For example, EUV light with a central wavelength of 13.5 nm can be used for EUV lithography. A common method for generating such EUV light is to irradiate a suitable material droplet with an intense laser pulse. This causes the material droplet to be at least partially vaporized or converted into a plasma which then emits EUV light. In order to enable efficient and reliable EUV light generation, it is expedient, for example, to first determine the position of the respective material droplet. For this purpose, a weaker pre-pulse or measurement laser pulse can be emitted which does not vaporize the material droplet, but only illuminates it and/or preconditions it for a stronger main laser pulse. Light reflected from the material droplet can then be analyzed to determine, for example, its position.

However, a number of problems and challenges can arise in this respect. For position determination, the laser pulse typically has to be directed or focused using an optical unit, which in turn can produce interfering reflections, however. These can overshadow or overlay the actual measurement signal, i.e., the light reflected by the material droplet, and thus impair the accuracy and reliability of the position determination. The use of a polarization-based filter mechanism can typically only filter out a part of the potentially interfering reflections and can also reduce the brightness or intensity of the reflected light to be measured for position determination in an ultimately undesirable manner.

### SUMMARY

Embodiments of the present invention provide an observation device for an extreme ultraviolet (EUV) light system for observing a material droplet for EUV light generation. The observation device includes an optical unit for focusing a measurement laser beam onto the material droplet and for directing light reflected by the material droplet along a predefined beam path, a sensor system arranged at an end of the beam path for detecting the reflected light, and at least one light-blocking element arranged between the optical unit and the sensor system, as viewed along the beam path, for keeping away interfering reflections of the measurement laser beam, which emanate from the optical unit in a direction of the sensor system at least in a central region of the beam path, such that at least a part of the reflected light can reach the sensor system along the beam path in spite of the light-blocking element.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a partial schematic representation of an EUV light system having an observation device for determining a position of a material droplet for EUV light generation according to some embodiments;

FIG. 2 shows a partial schematic representation of the observation device in a second variant according to some embodiments;

FIG. 3 shows a partial schematic representation of the observation device in a third variant according to some embodiments; and

FIG. 4 shows a partial schematic representation of the observation device in a fourth variant according to some embodiments.

### DETAILED DESCRIPTION

Embodiments of the present invention can enable accurate, reliable and efficient position determination of material droplets for EUV light generation.

The observation device according to embodiments of the invention can be used in an EUV light system for observing a light generation region, i.e., an interaction zone in which a material droplet can be vaporized or converted into a plasma to generate EUV light. This means that the observation device can be used, for example, to determine the position of a respective material droplet for EUV light generation. The observation device can also be used for further or other analyses. Such a material droplet can consist at least partially of a material, such as tin, which generates EUV light under laser irradiation of sufficient intensity for the at least partial vaporization of the material droplet. During operation of a corresponding EUV light system, such a material droplet can be created, for example, in a vacuum chamber or fall through a vacuum chamber. The observation device according to embodiments of the invention can be provided or configured for coupling to such a vacuum chamber or can comprise such a vacuum chamber.

The observation device according to embodiments of the invention has an optical unit for directing, i.e., in particular for the focusing or, for example, also for the prior collimation of a measurement laser beam or measurement laser pulse onto the material droplet or to an intended droplet position and for directing, i.e., for converging and focusing or also for collimating, for example, light reflected during operation from the respective material droplet along a predefined beam path. This beam path can lead through the optical unit in particular in a direction counter to the measurement laser beam or measurement laser pulse or can emanate from the optical unit. Furthermore, the observation device according to embodiments of the invention has a sensor system arranged at the other end of this beam path for receiving or detecting the reflected light. This detected and reflected light can then serve, for example, as a basis for determining the position of the respective material droplet and/or for determining or measuring a wavefront deformation and/or aberrations and/or the like. Such a sensor system can, for example, comprise a camera, a CCD chip or another light sensor. The sensor system can be equipped with or coupled to an appropriate evaluation electronics system. This allows a measurement or sensor signal generated by the sensor system upon receiving or detecting the reflected light to be analyzed, i.e., evaluated, in order to determine a predefined parameter value, for example the position of the respective material droplet. For this purpose, for example, an intensity distribution and/or wavefront and/or a phase distribution and/or the like can be evaluated.

According to embodiments of the invention, the observation device also has at least one light-blocking element. This is arranged between the optical unit and the sensor system, as viewed along the beam path, in order to keep away from the sensor system any interfering reflections of the measurement laser beam or the measurement laser pulse emanating from the optical unit in the direction of the sensor system during intended operation of the observation device or of the EUV light system equipped with it. This is also referred to in the present case as blocking the interfering reflections. In particular, the light-blocking element can be arranged in a region of the beam path in which the light reflected by the respective material droplet and/or the interfering reflections emanating from the optical unit is or are at least partially collimated. The light-blocking element can therefore prevent the interfering reflections from reaching the sensor system at least in a central region of the beam path. For this purpose, the light-blocking element can, for example, absorb light impinging on it or, in the case of a correspondingly wavelength-selective design, only the interfering reflections, but not the light reflected by the respective material droplet, or reflect or deflect it out of the beam path. For this purpose, the light-blocking element is arranged in the beam path at least in a central region, i.e., centrally in or relative to the radial cross-sectional plane of the beam path which is perpendicular to the light propagation direction given along the beam path. The beam path therefore describes a spatial region in which the light reflected by the respective material droplet is guided or propagated as intended, at least from the optical unit to the sensor system. The light-blocking element is designed and arranged in the beam path in such a way that, in spite of the light-blocking element, at least a part of the light reflected by the respective material droplet can reach the sensor system along the beam path.

For this purpose, in a possible embodiment of the invention, the size or diameter of the light-blocking element in the radial direction, i.e., as viewed in the cross-sectional plane, can be smaller than a diameter there, i.e., given at the position of the light-blocking element, of the beam path or the light distribution of the light which is reflected by the respective material droplet and directed or guided along the beam path during operation of the observation device or the EUV light system equipped therewith. Thus, the light-blocking element can be arranged and dimensioned in such a way that at least a part of the reflected light can pass the light-blocking element along the beam path to the sensor system. In other words, the light-blocking element can then be arranged in such a way that it only blocks the central region of the beam path or influences the propagation of the interfering reflections only there, but not in a part, for example annular part, of the beam path surrounding this central region or of the light distribution of the light reflected by the respective material droplet. The central position of the central region, i.e., this central arrangement of the light-blocking element, refers here to its position in the radial direction or cross-sectional plane perpendicular to the local longitudinal direction of extension of the beam path or to the central longitudinal axis of the beam path and not to the longitudinal position, i.e., not to the position in the longitudinal direction along the beam path or the light propagation direction. The light-blocking element is therefore not necessarily located halfway in the longitudinal or light propagation direction between the optical unit and the sensor system. The central longitudinal axis of the beam path can, in this regard, in particular correspond to the optical axis of the optical unit in its intended orientation—i.e., except for tolerances or unintentional misalignments. The design and dimensioning of the light-blocking element proposed here allows any influence or impairment of the light reflected by the respective material droplet by the light-blocking element to be kept particularly low. This means, for example, that the intensity of the light reflected by the respective material droplet, which is ultimately detected by the sensor system, can be kept particularly high and that a particularly precise and correct analysis of this reflected light can be made possible.

The light-blocking element can, for example, simply be a coating or a coated region of a larger element or component or a region of a component functionally designed to block the interfering reflections, which component can extend in the cross-sectional plane beyond it. Such a component can therefore be designed as the light-blocking element in some regions or can carry or comprise the light-blocking element. However, in another region of such a component, in particular the region surrounding the light-blocking element, this component may be designed differently or not be coated with the light-blocking element. In this other region, at least the reflected light can therefore pass the light-blocking element in order to reach the sensor system.

The at least one light-blocking element can therefore be a component of an optical element, such as a lens, of a plane-parallel plate, for example a plate that is partially and/or wavelength-selectively transparent, or the like. The light-blocking element can be designed as a coating that is at least partially opaque to interfering reflections. The light-blocking element can be formed from a material and/or a coating which is at least partially opaque to interfering reflections having a first wavelength and/or a first polarization and at least partially transparent to light which has a second wavelength and/or a second polarization and is reflected by the respective material droplet. The light-blocking element can extend radially, i.e., perpendicular to the local longitudinal direction of the beam path, in particular completely, over the beam path or the light distribution of the interfering reflections and completely or partially over the beam path or the light distribution of the light reflected by the respective material droplet.

A corresponding wavelength-selective and/or polarization-selective light-blocking element can be combined with one or more further light-blocking elements which can be completely opaque or at least partially opaque, regardless of the wavelength and/or polarization of the light.

The light-blocking element can be made of the same material, i.e., be designed as homogeneous. This can enable particularly simple and cost-effective production.

Likewise, the light-blocking element can also be made of different materials, i.e., be designed as inhomogeneous. A part of the light-blocking element arranged in the beam path or the light distribution of the interfering reflections can consist entirely or partially of a material and/or a coating or can comprise a material or a coating which is at least partially, preferably—at least almost—completely opaque to the interfering reflections. Another part of the light-blocking element, i.e., arranged in particular outside of the beam path or the light distribution of the interfering reflections, can consist entirely or partially of a different material and/or a coating or can comprise a material or a coating that is—at least largely—transparent to the light reflected by the respective material droplet. This enables, for example, a particularly simple and robust arrangement and mounting of the light-blocking element in the beam path. This means, for example, that no holding arms for holding the light-blocking element in the central region of the beam path need to protrude into the beam path, which could otherwise undesirably influence the light reflected by the respective material droplet.

In general, the arrangement and design of the light-blocking element can prevent the interfering reflections that impinge on it from reaching the sensor system. In this context, the light-blocking element can easily block, in particular, at least those interfering reflections that occur when the measurement laser beam impinges on the optical unit perpendicularly, i.e., at an angle of incidence of 0°. Such interfering reflections can also be referred to as perpendicular or straight interfering reflections. The corresponding light-blocking element can also be referred to as the first light-blocking element here. As explained in more detail elsewhere, one or more further light-blocking elements can also be provided and/or one or more other types of interfering reflections can be blocked.

Embodiments of the present invention are based on the finding that, in practice, the measurement laser beam has a significantly smaller numerical aperture, i.e., effectively a significantly smaller beam diameter, than the reflected light that can be used for position determination. Thus, for example, the light-blocking element can effectively punch out or eliminate, from the light distribution of the reflected light or the light reaching the sensor system, a central region including also the interfering reflections of the measurement laser beam or at least the interfering reflections, i.e., their wavelength or wavelengths. This can prevent the position determination from being affected by the interfering reflections. At the same time, the part of the reflected light that passes the light-blocking element and reaches the sensor system still allows the position of the respective material droplet to be determined without restriction, for example a corresponding analysis of the wavefront of the reflected light, for example to determine a focus position from a wavefront curvature or the like. In particular, the analysis, for example for determining the position of the respective material droplet, is not or not significantly impaired by the light-blocking element, since, due to the central arrangement or effect of the light-blocking element—for example its smaller effective diameter compared to the numerical aperture or the diameter of the light distribution of the reflected light or the corresponding beam path—the full numerical aperture, i.e., the full maximum size or the full maximum diameter of the light distribution of the reflected light, is retained and is thus available for the analysis. Although the arrangement of the light-blocking element in the beam path may result in the loss of information of higher frequency aberrations, this does not represent a significant limitation or impairment in practice.

The described embodiment of the invention can easily block at least interfering reflections collimated by the optical unit or interfering reflections with a relatively small opening or divergence angle using the light-blocking element. Depending on the application, the optimal longitudinal position of the light-blocking element and/or its diameter can be determined experimentally or by calculation or simulation. In particular, the light-blocking element can be arranged between a coupling point at which the measurement laser beam is coupled into the beam path and the sensor system. As a result, the irradiation of the respective material droplet with the measurement laser beam is not affected by the light-blocking element.

Embodiments of the present invention can enable a largely complete elimination of interfering reflections on the way to the sensor system, for example even in the case of a non-ideal anti-reflective coating of the optical unit. This, in turn, allows for a particularly precise, reliable and efficient analysis, for example to determine the position of the material droplets. In particular, for example, the power of the measurement laser beam does not need to be increased to compensate for intensity losses by a polarization-based filter mechanism, for example λ/4 wave plates or the like.

In one possible embodiment of the present invention, the at least one light-blocking element is designed in the form of a rod and is arranged in a longitudinally extending manner along a longitudinal axis of the beam path, in particular across focal regions of several different interfering reflections, such that interfering reflections propagating obliquely to the longitudinal axis can impinge on an outer lateral surface of the light-blocking element. The light-blocking element can be designed, for example, as a solid rod or as a hollow rod or tube. The longitudinal axis of the beam path can, at least in a simple embodiment of the observation device, at least substantially or at least in sections correspond to the optical axis of the optical unit or run parallel to it in the intended ideal arrangement. The design of the light-blocking element proposed here allows interfering reflections to be blocked not only at one end face of the light-blocking element facing the optical unit. Instead, a larger surface region is available in the form of the lateral surface to block the interfering reflections, for example to absorb them or to reflect them out of the beam path, or to deflect or diffract them so that they cannot reach the sensor system. The lateral surface of the rod-like light-blocking element can, for example, run at least substantially parallel to the local longitudinal direction of the beam path. The lateral surface can therefore surround a corresponding central beam path axis running in the longitudinal direction. Due to the longitudinal extension of the rod-like light-blocking element, it can be positioned particularly easily and with reduced precision or tolerance requirements to block the interfering reflections as completely as possible. The rod-like light-blocking element can, for example, extend over focal points or focal regions of several interfering reflections or several types of interfering reflections that may originate from or be caused by different locations or features of the optical unit. This may make it possible to eliminate the need for a further light-blocking element or to achieve a particularly simple and cost-effective design of the observation device.

In a further possible embodiment of the present invention, the observation device has an adjustment device for adjusting or displacing the light-blocking element. This means that the light-blocking element can be displaced, in particular along the beam path, i.e., in the longitudinal direction, for example manually or by motor or automated means. This allows the observation device to be used particularly flexibly and to be adapted to different conditions or properties of the optical unit, or to changes in these over time. This means that interfering reflections can be blocked particularly reliably and permanently, thus ensuring, accordingly, particularly reliable and permanently consistent performance of the observation device.

In one possible embodiment of the present invention, at least one aperture stop, which surrounds the beam path, is arranged between the optical unit and the sensor system, as viewed along the beam path. In other words, the aperture stop can limit the local cross-section, i.e., the maximum diameter of the beam path, at least at the location, i.e., the longitudinal position, of the aperture stop. The aperture stop can therefore have a central opening or a central translucent region through which the reflected light can pass, but at the same time block stray light into or from the surroundings of the beam path by an opaque region of the aperture stop surrounding the central opening or the central region. This allows further interfering reflections to be intercepted and thus prevented from reaching the sensor system. The aperture stop can be arranged in particular at the longitudinal position of the light-blocking element. The aperture stop can then surround the light-blocking element or be implemented on or in a common component with it. This can achieve particularly effective blocking or filtering of interfering reflections incident at different angles at this point. Overall, the aperture stop can enable further improvement in position determination. For this purpose, several aperture stops can also be arranged at different longitudinal positions along the beam path. These can, for example, have different sizes or opening widths, i.e., translucent inner diameters, if the beam path has, for example, a beam waist or a larger numerical aperture or a larger diameter at corresponding positions in each case. This may result in even more effective blocking of interfering reflections.

In a further possible embodiment of the present invention, the observation device has at least one optical coupling element for coupling the measurement laser beam into the beam path in the direction of the optical unit, i.e., also in the direction of the intended droplet position. This coupling element can in particular be an optical beam splitter, for example a partially transparent mirror or the like. The coupling element can be arranged tilted in particular at an angle between 0° and 90°, in particular of 45°, to the optical axis of the optical unit or to the local central longitudinal axis of the beam path. As viewed along the beam path, the coupling element is arranged between the optical unit and the sensor system here. In this way, the optical unit can be used both to focus the measurement laser beam onto the material droplet and to direct the corresponding reflected light from the material droplet to the sensor system. This enables a particularly simple and compact design of the observation device. Likewise, the measurement laser beam can be directed along the final beam path of the reflected light onto the material droplet, whereby a particularly high efficiency, i.e., a particularly high light yield of reflected light, which is ultimately detected by the sensor system, can be achieved compared to the intensity or brightness of the original measurement laser beam.

In a further possible embodiment of the present invention, the observation device has at least one further light-blocking element for blocking interfering reflections, i.e., for keeping interfering reflections away from the sensor system at least in or from the central region. This at least one further light-blocking element can therefore be arranged in the beam path in addition to the first light-blocking element. However, this at least one further light-blocking element is arranged at a different location in this regard than the first light-blocking element along the beam path, i.e., as viewed in the longitudinal or light propagation direction. The further light-blocking element can also be referred to here as a second light-blocking element or as an additional light-blocking element. The use of several light-blocking elements arranged centrally or which are effective with regard to the interfering reflections in the central region, but arranged at different longitudinal positions in the beam path, can enable a particularly effective and efficient blocking of different interfering reflections. Such different interfering reflections can, for example, be interfering reflections that are generated by different surfaces or different features or details of the optical unit and therefore emanate from the optical unit at different angles and/or have different divergence angles. Therefore, correspondingly different interfering reflections can, for example, have different focus positions. A respective light-blocking element can then be arranged at such a focus position. This allows different interfering reflections to be blocked by light-blocking elements of minimal effective diameter in each case. This ultimately not only allows the interfering reflections to be blocked particularly completely, but also allows a particularly large portion of the reflected light to pass past the light-blocking element, for example, or through a transparent region of the light-blocking element in order to reach the sensor system. This means that a correspondingly high level of efficiency can be achieved. If the corresponding positions at which several light-blocking elements were to be arranged are relatively close to one another, these positions could also be covered or blocked by a single, correspondingly elongated, for example rod-like, light-blocking element. Such an elongated light-blocking element can then extend, for example, to several focus positions of different types of interfering reflections or across several such focus positions. This may result in an even more complete blocking of the interfering reflections and/or a particularly simple design of the observation device.

In a further possible embodiment of the present invention, the first light-blocking element or a further light-blocking element, which can in particular be the further or second light-blocking element mentioned elsewhere or another such further light-blocking element or additional light-blocking element, is arranged in the region of a focal point of interfering reflections which are caused or generated by a concave surface of the optical unit, as viewed from the direction of the sensor system. Such a focal point can be located in particular between the coupling point of the measurement laser beam into the beam path and the sensor system. In such a case, corresponding interfering reflections originating from the concave surface and also referred to here as concave interfering reflection can be blocked particularly effectively and efficiently by a further light-blocking element arranged in the corresponding focal point. In this regard, the concave surface can be a surface that is shaped intentionally that way, i.e., on purpose, such as an inner side of a surface of a converging or focusing lens of the optical unit that faces the intended position of the material droplet. Likewise, there may be concave interfering reflections that can be caused by concave surface defects or unintentional malformations of the optical unit or a component of the optical unit. These can be blocked by appropriately arranging the further light-blocking element in the corresponding focal point, so that, despite the correspondingly non-ideal design of the optical unit, effective and reliable determination of the position of the material droplets is possible.

In a further possible embodiment of the present invention, the observation device comprises at least one imaging optical unit for imaging, i.e., for example for directing or focusing interfering reflections, for example onto or into a specific imaging plane or a specific focal point. The imaging optical unit can be arranged between the optical unit and the first light-blocking element, in particular as viewed along the beam path. Specifically, the imaging optical unit can be arranged between the first light-blocking element and the coupling point mentioned elsewhere or the coupling element mentioned elsewhere for coupling the measurement laser beam into the beam path. In principle, however, the imaging optical unit can be arranged completely or partially in front of and/or behind the coupling point of the measurement laser beam, as viewed along the beam path. In particular, the imaging optical unit can be configured and arranged to focus the one or more interfering reflections into a region which, as viewed along the beam path, is located on a side of the imaging optical unit facing away from the optical unit, in particular also from the coupling point for the measuring beam, i.e., facing the sensor system. Likewise, the imaging optical unit can be configured and arranged to at least partially collimate the light reflected by the respective material droplet and/or the interfering reflections. In particular, the imaging optical unit can be used to restore a collimation state of the light reflected by the respective material droplet, which it has before entering the imaging optical unit, during or after leaving the imaging optical unit. For example, the distance measured along the beam path between two lenses of the imaging optical unit can correspond to the sum of their focal lengths for this purpose.

The imaging optical unit can in particular be or comprise at least one relay telescope. Such a relay telescope can, for example, comprise at least or exactly two lenses. If the observation device or the imaging optical unit comprises several such relay telescopes, these can all be arranged before or all after the coupling point or the coupling element for the measurement laser beam, or partly before and partly after. Whether one relay telescope or several relay telescopes are used and/or how these are constructed or designed in detail, for example with regard to their focal lengths or the like, can be determined on a case-by-case basis, for example according to the complexity or variety of the interfering reflections. The imaging optical unit, in particular the at least one relay telescope, can therefore be designed as a lens optical unit. However, it is also possible to design the imaging optical unit as a mirror optical unit. For a particularly simple design, for example, two lenses with identical focal lengths can be used for the imaging optical unit and can be arranged in such a way that the respective image distance corresponds to the respective object distance. In principle, other designs and/or arrangements are also possible, for example with different lens focal lengths.

When using such an imaging optical unit or such a relay telescope, the aperture stop mentioned elsewhere or a further such aperture stop can be arranged in particular in the region of a beam waist resulting in the imaging optical unit, for example between its lenses or optical elements. There, an inner opening or transparency width, i.e., the inner free or transparent diameter of the aperture stop, can be particularly small without blocking the light reflected by the respective material droplet to be detected by means of the sensor system during operation. This allows unwanted stray light in or from the surroundings of the beam path to be blocked particularly effectively without any other restrictions, i.e., prevented from reaching the sensor system.

In a possible further embodiment of the present invention, the imaging optical unit has an adjustment device by means of which the position of a focal point of the imaging optical unit and/or a distance between optical elements, for example lenses or mirrors, of the imaging optical unit can be adjusted, in particular along the longitudinal direction of the beam path. In this way, as described elsewhere in connection with the adjustment device for displacing the light-blocking element, the observation device can be improved in terms of its flexibility and robustness as well as in terms of particularly simple and effective usability.

In a further possible embodiment, the imaging optical unit is configured to image a plane, in which interfering reflections on the optical unit arise due to a non-perpendicular incidence of the measurement laser beam on the optical unit, onto the light-blocking element or a further light-blocking element arranged, in particular as viewed along the beam path, between a coupling point of the measurement laser beam into the beam path and the sensor system. In other words, the imaging optical unit can be used to image interfering reflections onto the light-blocking element or onto or into its plane here, which occur when the measurement laser beam does not impinge perpendicularly, at an angle of incidence other than 0°, on the optical unit, i.e., an area or surface or a local surface region of the optical unit. This can happen, for example, due to a non-perfect coaxial alignment of the measurement laser beam with respect to the central longitudinal axis of the intended beam path or of the optical axis of the optical unit and/or due to an—intentional or unintentional—inclination or tilting of the optical unit or of at least one element of the optical unit causing the interfering reflection relative to the longitudinal axis of the intended beam path. Corresponding interfering reflections can also be referred to as oblique interfering reflections here. The oblique interfering reflections considered here can emanate from the optical unit at an acute angle relative to the longitudinal axis of the intended beam path. Thus, in principle, there could be at least a partial radial or lateral offset between the oblique interfering reflections or a corresponding interfering reflection light beam and the light-blocking element intended to block them. This, in turn, could in principle lead to these oblique interfering reflections at least partially passing or radiating past the light-blocking element. However, this offset can be compensated for by the imaging optical unit so that even such oblique interfering reflections can be imaged at least substantially completely onto the light-blocking element, in particular without, for example, its effective diameter having to be increased.

In a possible further embodiment of the present invention, the imaging optical unit is configured, i.e., designed or constructed accordingly, to image the focal point of so-called convergent interfering reflections onto or into a second focal point between the coupling point of the measurement laser beam into the beam path and the sensor system. In the present case, such convergent interfering reflections can be caused by a concave surface of the optical unit, as viewed from the direction of the sensor system, whether intentionally or unintentionally. This concave surface can then focus any interfering reflections that occur at the focal point determined by the curvature of the concave surface, which can also be referred to as the natural or first focal point. In this regard, this first focal point can be located in the beam path between the optical unit and the coupling point at which the measurement laser beam is coupled into the beam path. A further light-blocking element arranged at this first focal point could thus, on the one hand, effectively block the convergent interfering reflections, but, on the other hand, would also at least partially block the measurement laser beam and thus ultimately reduce the amount of light effectively available for determining the position of the respective material droplet.

In order to avoid this, in the further embodiment of the invention proposed here, the first light-blocking element or a further light-blocking element is arranged in the region of the second focal point. This further light-blocking element can be the further or second light-blocking element mentioned elsewhere or another further light-blocking element. In particular, the same light-blocking element can be used to block several different types of interfering reflections if the corresponding focal lengths are the same or—depending on the size of the light-blocking element or the diameter of the light distributions of the interfering reflections—sufficiently similar. Otherwise, several light-blocking elements can be used at different longitudinal positions along the beam path.

In the further embodiment of the present invention proposed here, the imaging optical unit can therefore be configured to image or focus convergent interfering reflections in the region between the coupling point of the measurement laser beam and the sensor system onto the light-blocking element or onto the further light-blocking element. The imaging optical unit or at least a corresponding part of the imaging optical unit can be arranged in particular between the coupling point for the measurement laser beam and the sensor system. This prevents any impairment or attenuation of the measurement laser beam on its way to the optical unit or the respective material droplet by the corresponding light-blocking element. The further embodiment of the present invention proposed here can be particularly useful in particular when the natural or first focal point, which results directly from the concave surface of the optical unit, is located between the optical unit and the coupling point of the measurement laser beam. The imaging optical unit can then efficiently and particularly completely block corresponding convergent interfering reflections without hindering the radiation of the measurement laser beam to the respective material droplet. By appropriately adapting or designing the imaging optical unit, the second focal point can be positioned flexibly, allowing for a flexible adaptation to specific installation space conditions or other requirements, for example. This can, for example, enable a particularly flexible and/or particularly simple structure of the observation device as well as a particularly complete blocking of the convergent interfering reflections by means of a particularly small light-blocking element. This, in turn, can lead to or contribute to a particularly high light yield for determining the position of the respective material droplet so that this position determination can then be achieved in a particularly accurate, reliable and efficient manner.

In a possible further embodiment of the present invention, the imaging optical unit comprises at least two lenses. In this regard, the focal length of at least the lens on the optical unit side, i.e., the lens facing the optical unit as viewed along the beam path, corresponds to its distance from the first focal point. The convergent interfering reflections are then guided between the two lenses of the imaging optical unit as a collimated, i.e., at least substantially neither convergent nor divergent, beam. In other words, the convergent interfering reflections between the lenses of the imaging optical unit can be guided as a parallel beam or parallel beam bundle. For example, the two lenses of the imaging optical unit can be identical, wherein the distance between the two lenses can then correspond to twice their focal length. Depending on the design, the first light-blocking element or the further light-blocking element mentioned elsewhere or another further light-blocking element can then be arranged between the sensor-side lens of the imaging optical unit and the sensor system at a distance corresponding to this focal length. In this way, the convergent interfering reflections can be blocked effectively and efficiently with a particularly simple and cost-effective design of the observation device. In principle, however, other embodiments of the imaging optical unit or other arrangements of the lenses of the imaging optical unit and/or of the corresponding light-blocking element are also possible.

In a further possible embodiment of the present invention, the imaging optical unit is configured to image or focus so-called divergent interfering reflections onto the light-blocking element or the further light-blocking element mentioned elsewhere and arranged, as viewed along the beam path, in particular between a coupling point of the measurement laser beam into the beam path and the sensor system, or onto another further light-blocking element. Such divergent interfering reflections can arise here as a result of an—intentionally or unintentionally—convex surface of the optical unit, as viewed from the direction of the sensor system. This is another type of interfering reflection. Without the imaging optical unit, the diameter of these divergent interfering reflections or their light distribution would increase with increasing distance from the optical unit. Therefore, such divergent interfering reflections could then, for example, at least partially pass the first light-blocking element and reach the sensor system—for example after an uncontrolled reflection at an inner side of a housing surrounding the beam path and/or at least one other component of the observation device. This can be avoided by the embodiment of the imaging optical unit proposed here for converging or focusing such divergent interfering reflections onto a light-blocking element arranged centrally in the beam path or into a corresponding plane. Thus, a corresponding interference with respect to the analysis of the light reflected by the respective material droplet, such as the position determination of the respective material droplet, by such divergent interfering reflections can be effectively and efficiently avoided or at least reduced.

If several light-blocking elements are used to block the different types of interfering reflections, they can be designed the same or differently, for example they can have the same or different sizes or diameters. This may, for example, depend on a practically achievable focus for the different interfering reflections and/or on the possibilities or limitations given in a particular case with regard to the positionability of the light-blocking elements in the respective focal point or the focal plane and/or the like. The individually minimized size of the light-blocking elements can also minimize the—ultimately unintentional—blocking of light reflected by the respective material droplet. By using identical light-blocking elements, i.e., a corresponding common parts strategy, a particularly simple and cost-effective design of the observation device can be made possible, for example.

Embodiments of the present invention also relate to an EUV light system which has or comprises the observation device according to embodiments of the invention. The EUV light system according to embodiments of the invention can be configured or designed, for example, for EUV lithography. Therefore, the EUV light system according to embodiments of the invention can comprise further components, for example at least one or more laser sources for the measurement laser beam and for a main laser beam for vaporizing the respective material droplet and/or a corresponding beam guide and/or, for example, also a beam guide or optical unit for converging or guiding the generated EUV light and/or the like. However, the EUV light system according to embodiments of the invention can also be designed or configured for other applications, for example.

Further features of the embodiments of the invention may be found from the following description of the figures and with the aid of the drawing. The features and combinations of features mentioned above in the description as well as the features and combinations of features shown below in the description of the figures and/or in the figures alone can be used not only in the combination indicated in each case, but also in other combinations or on their own.

Identical or functionally identical elements are provided with the same reference signs in the figures.

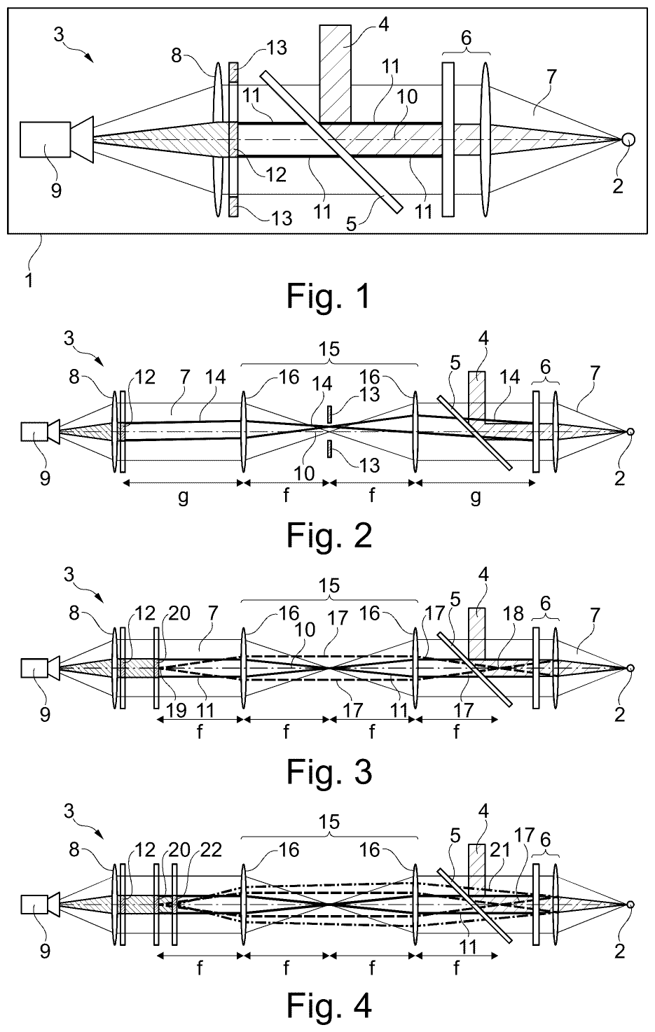

FIG. 1 shows a partial schematic representation of an EUV light system 1. In this system, for example, a material droplet 2, for example a tin drop, can be at least partially vaporized or converted into a plasma by means of a laser or one or more laser pulses, which then leads to the emission of extreme ultraviolet radiation.

In order to be able to hit the material droplet 2 precisely, it is useful to first carry out a corresponding position determination. For this purpose, the EUV light system 1 has an observation device 3, which in this case functions or can be used, at least among other things, as a position determination device. In order to determine the position of the respective material droplet 2, it can be illuminated with a pulse of a measurement laser beam 4 indicated here. The measurement laser beam 4 or the corresponding laser pulse is also referred to as a pre-pulse, since it is emitted before a main laser pulse for vaporizing the material droplet 2 and is significantly weaker than this main laser pulse so that the material droplet 2 can be illuminated or preconditioned, for example expanded, by the measurement laser beam 4, but is not vaporized. The measurement laser beam 4 can be coupled here via a coupling element 5 and deflected in the direction of the material droplet 2. The measurement laser beam 4 can then pass through an optical unit 6 of the observation device 3 and thereby be focused on the material droplet 2.

The material droplet 2 can then reflect the light of the measurement laser beam 4 as reflected measuring light 7. Here, this reflected measuring light 7 also radiates through the optical unit 6 in the opposite direction. In this regard, the reflected measuring light 7 can be collimated, for example, as indicated here. The reflected measuring light 7 is then guided along a corresponding beam path and can then be focused, for example via a detection optical unit 8, onto a sensor system 9 of the observation device 3. For further illustration and clarification, a central beam path axis 10 of the intended beam path of the reflected measuring light 7 is schematically indicated here.

The sensor system 9 can, for example, comprise a camera and a corresponding measuring and evaluation electronics system. In general, the sensor system 9 can therefore comprise at least one position-sensitive sensor. This means that the position of the material droplet 2 can ultimately be determined using the reflected measuring light 7. For this purpose, for example, parameters of the beam path or the optical elements or other configurations of the observation device 3 can be predefined and taken into account.

In the method described so far, a part of the light of the measurement laser beam 4 can be reflected on its way to the respective material droplet 2, for example at surfaces and/or material defects and/or damage and/or the like of the optical unit 6. This leads to corresponding interfering reflections, which can also be referred to as ghost reflections. Where such interfering reflections are generated and how strong they are may depend, for example, on the configuration of the optical unit 6 as well as on its material, quality, surface properties, coating and/or the like. In principle, however, such interfering reflections can be so strong that they can cover the reflection of the measurement laser beam 4, i.e., the reflected measuring light 7, which is actually desired for determining the position of the respective material droplet 2. If in such a case the interfering reflections reach the sensor system 9, i.e., are also detected by it, the position determination of the material droplet 2 can be impaired.

In order to counteract this problem, advantage can be taken of the fact that the measurement laser beam 4 has a significantly smaller numerical aperture, i.e., a significantly smaller diameter than the reflected measuring light 7 used for position determination or its beam path. Therefore, if the measurement laser beam 4 impinges on a surface of the optical unit 6 perpendicularly and the optical unit is oriented without tilting relative to the beam path axis, i.e., with an optical axis that is at least substantially coaxial or coincident with the beam path axis 10, it generates, for example, a straight interfering reflection 11, which propagates at least substantially only in a center, i.e., a central region of the beam path and thus also of the light distribution of the reflected measuring light 7 in the direction of the sensor system 9. This straight interfering reflection 11, like the reflected measuring light 7, can pass through the coupling element 5 and propagate further along the beam path in the direction of the sensor system 9. In the present case, however, the observation device 3 comprises a first light-blocking element 12 which is arranged in the corresponding central region of the beam path. This first light-blocking element 12 thus blocks the further propagation of the straight interfering reflection 11. In this regard, the diameter of the first light-blocking element 12 is smaller than the diameter of the beam path or of the light distribution of the reflected measuring light 7. As a result, a part, in particular a majority, of the reflected measuring light 7 can pass past the first light-blocking element 12 to the sensor system 9.

However, the diameter of the first light-blocking element 12 can be larger here than the diameter of the light distribution of the straight interfering reflection 11. As a result, the straight interfering reflection 11 can be completely or at least largely prevented from reaching the sensor system 9.

A central or middle region around the beam path axis 10 can also be referred to as the near field. A region further away from the beam path axis 10 can also be referred to as the far field. The first light-blocking element 12 can therefore block not only the straight interfering reflection 11, but also a near-field region of the reflected measuring light 7. However, this does not change the imaging of the reflected measuring light 7 in the far field onto the sensor system 9, so, in spite of the first light-blocking element 12, position determination of the respective material droplet 2 is still possible on the basis of the portion of the reflected measuring light 7 detected by the sensor system 9.

In order not to influence the measurement laser beam 4 in this case, the first light-blocking element 12 is arranged behind the coupling element 5, as viewed along the beam path, i.e., between this coupling element or the corresponding coupling point at which the measurement laser beam 4 is coupled into the beam path and the sensor system 9.

In addition, an outer aperture stop 13 is arranged here—for example at the location or at the level of the first light-blocking element 12. This aperture stop 13 surrounds the beam path, for example annularly. As a result, a region remains between the aperture stop 13 and the first light-blocking element 12, through which region the reflected measuring light 7 can pass in order to reach the sensor system 9. The aperture stop 13 can accordingly intercept, i.e., block, external stray light.

The straight interfering reflection 11 is shown here as a collimated beam or collimated beam bundle. However, there may also be non-collimated interfering reflections or interfering reflection components that, for example, run obliquely to the beam path axis 10 and/or diverge or converge. Such interfering reflections can be converged or focused, for example, by suitable optical elements arranged in front of and/or behind the coupling element 5. Further light-blocking elements can be arranged in corresponding focal planes or focus positions, provided that these do not coincide with the position of the first light-blocking element 12. With an appropriately adapted arrangement, various types of interfering reflections can also be blocked, i.e., eliminated. In this way, interfering reflections outside of the near field or the central region covered by a light-blocking element can be captured and directed or imaged into this central region. Thus, for example, corresponding angular deviations between the propagation direction or the central longitudinal axis of corresponding interfering reflections emitted or emanating from the optical unit 6 at an angle to the beam path axis 10 can also be corrected. Examples of this are shown in the remaining figures and are explained below. Differences and additions with respect to the observation device 3 shown in FIG. 1 are mainly discussed in this respect.

FIG. 2 shows a schematic representation of the observation device 3 in a second variant. In this case, for example, one of the elements of the optical unit 6 is inclined, i.e., tilted relative to the beam path axis 10. As a result, the measurement laser beam 4 impinges on this element of the optical unit 6 at an angle of incidence different from 0°. This, in turn, creates an oblique interfering reflection 14, which propagates at an angle, i.e., not parallel to the beam path axis 10. This oblique interfering reflection 14 could in principle radiate past the first light-blocking element 12. In order to also prevent such oblique interfering reflections 14 from reaching the sensor system 9, the observation device 3 in this case also comprises an imaging optical unit 15 arranged in the beam path. This can be designed, for example, with two telescope lenses 16 as a relay telescope. By means of the imaging optical unit 15, the oblique interfering reflection 14 which impinges on the optical unit-side or droplet-side telescope lens 16, i.e., facing the optical unit 6 or the region of the material droplet 2 in the intended installation position, at least partially outside of the central region covered by the first light-blocking element 12 is directed or imaged into the central region. Thus, the oblique interfering reflection 14 can also be imaged onto the first light-blocking element 12 and thus blocked by it. For example, the telescope lenses 16 here each have a focal length f and are each arranged at a distance of the object distance g from the optical unit 6 or the plane of the first light-blocking element 12.

This results in a beam waist with a minimum diameter of the light distribution of the reflected measuring light 7 within the imaging optical unit 15, i.e., between its telescope lenses 16. The or a further aperture stop 13 is arranged in this region. By arranging them in the region of the beam waist in this case, an inner opening or transparency region of the aperture stop 13 can be selected to be particularly small without blocking the reflected measuring light 7. This allows interfering stray light to be blocked particularly effectively by the aperture stop 13. Ultimately, however, the aperture stop 13 is optional and flexible in its positioning along the beam path, i.e., in its longitudinal position. Likewise, several aperture stops 13 can be used at different longitudinal positions along the beam path, which may be the same or different.

FIG. 3 shows the observation device 3 in a third variant. Here, a concave interfering reflection 17 is illustrated as another type of interfering reflection. This can originate or be generated by a surface of the optical unit 6 which is concave as viewed from the perspective of the sensor system 9. The concave interfering reflection 17 can be focused in a focal point 18 by the correspondingly concavely curved surface of the optical unit 6. However, this focal point 18 can be located between the coupling element 5 and the optical unit 6. Thus, it would not be practical to block the concave interfering reflection 18 in the focal point 18 itself, since then the measurement laser beam 4 would also be at least partially blocked there. Instead, the or an imaging optical unit 15 is also provided here. This first collimates the concave interfering reflection 17 and then focuses it in a second focal point 19, which lies between the coupling element 5 and the sensor system 9. If this second focal point 19 lies in the region of the first light-blocking element 12, the concave interfering reflection 17 can then also be blocked by the first light-blocking element 12.

In the present example, however, the second focal point 19 is located in a different plane, i.e., at a different longitudinal position along the beam path or the beam path axis 10 than the first light-blocking element 12. In order to block the concave interfering reflection 17 effectively and efficiently, a second light-blocking element 20 is therefore arranged in the region of the second focal point 19. In order to ensure the arrangement of the second light-blocking element 20 in the second focal point 19, the second light-blocking element 20 can be adjustable along the beam path axis 10, for example by means of an adjustment device. Additionally or alternatively, the imaging optical unit can be designed to be variable, i.e., adjustable. For this purpose, at least one of the telescope lenses can be tilted relative to the beam path axis 10 and/or displaced along the beam path axis 10, for example by means of a corresponding adjustment device. Thus, for example, the second focal point 19 can be shifted onto the beam path axis 10 and/or along the beam path axis 10 so that it coincides with the second light-blocking element 20. Likewise, the first light-blocking element 12 and/or further light-blocking elements and/or optical elements of the observation device 3 can be adjustable or displaceable. Corresponding adjustment devices can have, for example, one or more adjusting screws and/or a servo motor, in particular an electric servomotor, and/or at least one Bowden cable and/or the like for the adjustment or displacement. If the imaging optical unit 15 has a sufficiently large adjustment range and/or the first light-blocking element 12 is adjustable far enough, the second focal point 19 can coincide with the position of the first light-blocking element 12. In other words, the first light-blocking element 12 can then be arranged in the second focal point 19 and take the place of the second light-blocking element 20. This may make it possible to omit the separate second light-blocking element 20.

By way of example, the telescope lenses 16 of the imaging optical unit 15 are designed and arranged in this case such that they have identical focal lengths f and these focal lengths f also correspond to the distance of the telescope lens 16 on the optical unit side or droplet side from the focal point 18 and the distance of the telescope lens 16 on the sensor system side from the second focal point 19 or the second light-blocking element 20. However, other arrangements may also be possible and/or other configurations may arise, for example, by shifting at least one of the telescope lenses 16, in particular along the beam path axis 10.

FIG. 4 shows a schematic representation of the observation device 3 in a fourth variant. In addition to the straight interfering reflection 11 and the concave interfering reflection 17, a convex interfering reflection 21 is also shown here by way of example. This can be generated or originate from a surface of the optical unit 6 that is convex as viewed from the perspective of the sensor system 9. Thus, the convex interfering reflection 21 in the region between the coupling element 5 and the optical unit 6 can, for example, have a larger cross-section or diameter than the actual measurement laser beam 4 there, so the convex interfering reflection 21 cannot practically be blocked there. In this case also, the observation device 3 comprises the or an imaging optical unit 15. This is configured in this case to focus the convex interfering reflection 21 in the region between the coupling element 5 and the sensor system 9. At the longitudinal position of the corresponding focus, a third light-blocking element 22 is arranged here, by way of example, to block the convex interfering reflection 21.

Although this is not explicitly shown here for the sake of clarity, one or more aperture stops 13 can also be provided in the variants according to FIG. 3 and FIG. 4. Likewise, several relay telescopes can be used in combination with each other and/or the imaging optical unit 15 can comprise more than just two telescope lenses 16 and/or further optical elements.

The light-blocking elements 12, 20, 22 can, for example, be designed as plane-parallel plates comprising a central region that at least or only selectively absorbs and/or reflects the wavelength or wavelengths of the interfering reflections 11, 14, 17, 21. The central region or at least a remaining region surrounding it, i.e., extending in the region of the far field, of these plates can be transparent in each case at least to the reflected measuring light 7. This can enable particularly simple mounting or fastening of the light-blocking elements 12, 20, 22. The light-blocking elements 12, 20, 22 can, for example, be arranged perpendicular to the beam path axis 10. Likewise, the light-blocking elements 12, 20, 22 can be tilted relative to the beam path axis 10 or a propagation plane of the reflected measuring light 7, for example at an angle in the range of 2° to 45°. In this case in particular, the light-blocking elements 12, 20, 22 can be designed, for example, as reflecting mirrors. The unwanted interfering reflections 11, 14, 17, 21 can then be deflected out of the beam path by the light-blocking elements 12, 20, 22 so that they cannot reach the sensor system 9. In this case, different variants and/or arrangements of light-blocking elements can also be combined, such that the light-blocking elements 12, 20, 22 can be designed and/or arranged in the same or different ways. Likewise, several light-blocking elements 12, 20, 22 shown individually here can, for example, be combined or replaced by an absorbing or reflecting rod or cylinder or the like, in particular one that extends longitudinally along the beam path axis 10. Such a rod-like light-blocking element 12, 20, 22, i.e., one that extends longitudinally along the beam path axis 10, may be easier to position in order to achieve the desired effect and, with a particularly small diameter, can keep a particularly large part of the interfering reflections 11, 14, 17, 21 away from the sensor system 9. For example, such a rod-like light-blocking element 12, 20, 22 does not necessarily have to be positioned precisely in a focal plane of one of the interfering reflections 11, 14, 17, 21, since it can extend along the beam path axis 10 over one or even several corresponding focal regions or beyond. For example, even if the position of the second focal point 19 is not precisely known or if a shift occurs during operation, a rod-like light-blocking element 12, 20, 22 can continue to prevent the corresponding interfering reflection 17 from reaching the sensor system 9. In this case, for example, light of at least one of the interfering reflections 11, 14, 17, 21 can fall onto an outer lateral surface of the rod-like light-blocking element 12, 20, 22. The lateral surface can, for example, be designed to be absorbent—at least for the corresponding wavelength or wavelengths of at least one of the interfering reflections 11, 14, 17, 21. Likewise, a surface of the light-blocking element 12, 20, 22 can be structured or microstructured at least in some regions in such a way that light incident there is reflected—optionally wavelength-selectively for at least one of the interfering reflections 11, 14, 17, 21—away from the sensor system 9. Overall, the rod-like design of at least one of the light-blocking elements 12, 20, 22 can reduce the required number of light-blocking elements and/or simplify their arrangement. Likewise, the observation device can be designed to be particularly robust, for example against vibrations or relative movements of components or changes in optical properties and/or geometries, for example due to thermal influences or the like.

In an individual case of application, the optimal longitudinal positions and sizes of the described components can be determined, for example, using the usual optical formulas.

In addition to the variants shown here by way of example, other variants or variations are also possible. For example, the measurement laser beam 4 can be radiated or coupled in obliquely with respect to the beam path axis 10 or offset parallel to it. In the latter case, the beam path axis 10 for the reflected measuring light 7 and a central longitudinal axis of the measurement laser beam 4 would not necessarily coincide. Likewise, the or a further imaging optical unit 15 can be arranged wholly or partially between the coupling element 5 and the optical unit 6. Likewise, the reflected measuring light 7 can be guided to the sensor system 9, for example, along a differently designed, for example angled or tilted, beam path. These and/or other possible variations or adaptations can allow for a particularly flexible adaptation of the observation device 3 to different requirements and/or installation space conditions and/or the like.

Overall, the described examples show how, in the context of EUV light generation, unwanted reflections during the position determination of the ultimately light-generating material can be avoided or at least reduced effectively and efficiently compared to previous approaches.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

1 EUV light system
2 Material droplet
3 Observation device
4 Measurement laser beam
5 Coupling element
6 Optical unit
7 Reflected measuring light
8 Detection optical unit
9 Sensor system
10 Beam path axis
11 Straight interfering reflection
12 First light-blocking element
13 Aperture stop
14 Oblique interfering reflection
15 Imaging optical unit
16 Telescope lenses
17 Concave interfering reflection
18 Focal point
19 Second focal point
20 Second light-blocking element
21 Convex interfering reflection
22 Third light-blocking element
f Focal length
g Object distance

1. An observation device for an extreme ultraviolet (EUV) light system for observing a material droplet for EUV light generation, the observation device comprising:
an optical unit for focusing a measurement laser beam onto the material droplet and for directing light reflected by the material droplet along a predefined beam path,
a sensor system arranged at an end of the beam path for detecting the reflected light, and
at least one light-blocking element arranged between the optical unit and the sensor system, as viewed along the beam path, for keeping away interfering reflections of the measurement laser beam, which emanate from the optical unit in a direction of the sensor system at least in a central region of the beam path, such that at least a part of the reflected light can reach the sensor system along the beam path in spite of the light-blocking element.

2. The observation device according to claim 1, wherein
a diameter of the at least one light-blocking element is smaller than a local diameter of a light distribution of the reflected light guided along the beam path.

3. The observation device according to claim 1, wherein
the at least one light-blocking element is configured in a form of a rod and is arranged in a longitudinally extending manner along a longitudinal axis of the beam path, across focal regions of several different ones of the interfering reflections, such that the interfering reflections propagating obliquely to the longitudinal axis can impinge on an outer lateral surface of the light-blocking element.

4. The observation device according to claim 1, further comprising:
an adjustment device, wherein the light-blocking element is arranged to be displaceable by the adjustment device along the beam path.

5. The observation device according to claim 1, further comprising:
an aperture stop, as viewed along the beam path, surrounding the beam path and being arranged between the optical unit and the sensor system, at a longitudinal position of the light-blocking element.

6. The observation device according to claim 1, further comprising:
a coupling element, for coupling the measurement laser beam into the beam path, wherein the coupling element is arranged, as viewed along the beam path, between the optical unit and the sensor system.

7. The observation device according to claim 1, further comprising:
at least one further light-blocking element for keeping the interfering reflections away from the sensor system at least in the central region of the beam path, wherein the at least one further light-blocking element is arranged at a different location than the at least one light-blocking element, as viewed along the beam path.

8. The observation device according to claim 1, wherein
the at least one light-blocking element is arranged in a region of a focal point of the interfering reflections, wherein the focal point is determined by a concave surface of the optical unit, as viewed from the direction of the sensor system.

9. The observation device according to claim 1, further comprising:
an imaging optical unit arranged in the beam path, as viewed along the beam path, between the optical unit and the at least one light-blocking element, for imaging the interfering reflections.

10. The observation device according to claim 9, further comprising:
an adjustment device, wherein a position of a focal point of the imaging optical unit and/or a distance between optical elements of the imaging optical unit, along the longitudinal direction of the beam path, is adjustable by the adjustment device.

11. The observation device according to claim 9, wherein
the imaging optical unit is configured to image a plane in which the interfering reflections at the optical unit arise due to a non-perpendicular incidence of the measurement laser beam on the optical unit onto the at least one light-blocking element.

12. The observation device according to claim 9, wherein
the imaging optical unit is configured for the interfering reflections that are convergent and arise due to a concave surface of the optical unit, as viewed from the direction of the sensor, and have a focal point located in the beam path between the optical unit and a coupling point of the measurement laser beam in the beam path, wherein the imaging optical unit is configured to image the focal point into a second focal point between the coupling point and the sensor system, and wherein the at least one light-blocking element is arranged in a region of the second focal point.

13. The observation device according to claim 12, wherein
the imaging optical unit comprises two lenses, wherein a focal length of an optical unit-side lens of the two lenses corresponds to a distance from the focal point to the optical unit-side lens, such that the convergent interfering reflections between the two lenses of the imaging optical unit are guided as a collimated beam.

14. The observation device according to claim 9, wherein
the imaging optical unit is configured to image the interfering reflections that are divergent and arise due to a convex surface of the optical unit, as viewed from the direction of the sensor system, onto the at least one light-blocking element.

15. An extreme ultraviolet (EUV) light system, comprising an observation device according to claim 1.
